(19) United States
(12) Patent Application Publication
(10) Pub. No.: US 2026/0096450 A1
(43) Pub. Date: Apr. 2, 2026

(54) PACKAGE GROOVES TO INHIBIT DELAMINATION

(71) Applicant: TEXAS INSTRUMENTS INCORPORATED, Dallas, TX (US)

(72) Inventors: Xiaoling KANG, Chengdu (CN); Xi Lin LI, Chengdu (CN); Zi Qi WANG, Deyang (CN); Xiao Lin KANG, Chengdu (CN)

(21) Appl. No.: 18/902,506

(22) Filed: Sep. 30, 2024

(51) Int. Cl. H01L 23/495; H01L 23/00; H01L 23/31

(52) U.S. Cl. CPC H10W 70/438; H10W 70/427; H10W 72/075; H10W 74/111; H10W 90/756

(57) ABSTRACT

A semiconductor package includes a semiconductor die; a die pad having a first surface coupled to the semiconductor die and a second surface opposite the first surface, the die pad including an extension that comprises a first V-shaped groove in the second surface; a first conductive terminal having first and second ends and a third surface facing a same direction as the second surface, the third surface comprising a second V-shaped groove; a second conductive terminal having third and fourth ends and a fourth surface facing the same direction as the second surface, the fourth surface comprising a third V-shaped groove, the extension in between the second and fourth ends; and a mold compound covering the die, the die pad, and the first and second conductive terminals, the mold compound filling the first, second, and third V-shaped grooves, and the first and third ends extending to an exterior of the mold compound.

### BACKGROUND

A semiconductor package may include a semiconductor die and a housing to cover the semiconductor die. The semiconductor package may further include conductive terminals exposed to an exterior surface of the housing. The conductive terminals are coupled to the semiconductor die. The conductive terminals provide electrical pathways between circuitry on the semiconductor die and components (e.g., printed circuit boards) outside of the semiconductor package.

### SUMMARY

In examples, a semiconductor package includes a semiconductor die; a die pad having a first surface coupled to the semiconductor die and a second surface opposite the first surface, the die pad including an extension that comprises a first V-shaped groove in the second surface; a first conductive terminal having first and second ends and a third surface facing a same direction as the second surface, the third surface comprising a second V-shaped groove; a second conductive terminal having third and fourth ends and a fourth surface facing the same direction as the second surface, the fourth surface comprising a third V-shaped groove, the extension in between the second and fourth ends; and a mold compound covering the die, the die pad, and the first and second conductive terminals, the mold compound filling the first, second, and third V-shaped grooves, and the first and third ends extending to an exterior of the mold compound.

In examples, a method for manufacturing a semiconductor package includes coupling a semiconductor die to a die pad, the die pad including an extension. The method includes wire bonding the semiconductor die to first and second conductive terminals, with the extension extending between the first and second conductive terminals. A first groove in the extension extends across an entire width of the extension, a second groove extends across a portion of the first conductive terminal, and a third groove extends across a portion of the second conductive terminal. The first, second, and third grooves are aligned such that a line extends through the first, second, and third grooves. The method includes covering the semiconductor die, the die pad, and the first and second conductive terminals with a mold compound and filling the first, second, and third grooves with the mold compound.

### BRIEF DESCRIPTION OF THE DRAWINGS

FIG. 1 is a block diagram of an electronic device including a semiconductor package having grooves to inhibit mold compound delamination, in accordance with various examples.

FIG. 2A is a top-down view of a die pad and conductive terminals having grooves to inhibit mold compound delamination, in accordance with various examples.

FIG. 2B is a bottom-up view of a die pad and conductive terminals having grooves to inhibit mold compound delamination, in accordance with various examples.

FIG. 2C is a profile, cross-sectional view of a semiconductor package having die pad and conductive terminal grooves to inhibit mold compound delamination, in accordance with various examples.

FIG. 2D is a profile, cross-sectional view of a semiconductor package having die pad and conductive terminal grooves to inhibit mold compound delamination, in accordance with various examples.

FIGS. 2E and 2F are perspective views of a semiconductor package having die pad and conductive terminal grooves to inhibit mold compound delamination, in accordance with various examples.

FIG. 2G is a cross-sectional view of a delamination-inhibiting groove in a metal component of a semiconductor package, in accordance with various examples.

FIG. 2H1-2H3 are cross-sectional, top-down, and perspective views of a die pad and conductive terminals having grooves to inhibit mold compound delamination, in accordance with various examples.

FIG. 2I1-2I3 are cross-sectional, top-down, and perspective views of a die pad and conductive terminals having grooves to inhibit mold compound delamination, in accordance with various examples.

FIG. 2J1-2J3 are cross-sectional, top-down, and perspective views of a die pad and conductive terminals having grooves to inhibit mold compound delamination, in accordance with various examples.

FIG. 3 is a flow diagram of a method for manufacturing a semiconductor package having grooves to inhibit mold compound delamination, in accordance with various examples.

FIGS. 4A-4I2 are a process flow of a method for manufacturing a semiconductor package having grooves to inhibit mold compound delamination, in accordance with various examples.

### DETAILED DESCRIPTION

Mold compound delamination from lead frames in semiconductor packages presents a significant technical challenge that can severely impact the reliability and performance of electronic components. This phenomenon typically occurs due to the differences in the thermal expansion coefficients between the mold compound and the lead frame material. When these materials are subjected to thermal cycling during manufacturing or operational conditions, the repeated expansion and contraction can create mechanical stresses at the interface, leading to delamination.

Additionally, moisture penetration can exacerbate this issue. Specifically, moisture can penetrate the mold compound and accumulate at the interface, causing hydrolysis and weakening the bond between the mold compound and the lead frame. Contaminants and impurities on the lead frame surface before mold compound application can also hinder proper adhesion, further increasing the risk of delamination. Moreover, inadequate curing of the mold compound can leave the mold compound with insufficient mechanical strength, making the mold compound more prone to separation.

Further still, the presence of voids and cracks within the mold compound, often resulting from improper molding processes, can serve as initiation points for delamination. Such separation can lead to a variety of failures, including electrical shorts, increased thermal resistance, and compromised structural integrity, ultimately resulting in device malfunction or failure.

This disclosure describes various examples of a semiconductor package having delamination-inhibiting grooves in a die pad and conductive terminals (e.g., leads), thereby mitigating the risk of the technical challenges described above. In some examples, a semiconductor package comprises a semiconductor die. The semiconductor package also includes a die pad having a first surface plated with silver and coupled to the semiconductor die and a second surface opposite the first surface. The die pad includes an extension that comprises a first V-shaped groove in the second surface, where the first V-shaped groove has a length extending across an entire width of the extension, and where an edge of the extension at the second surface is curved to have a rounded shape. The semiconductor package also comprises a first conductive terminal having first and second ends and a third surface facing a same direction as the second surface. The third surface includes a second V-shaped groove, with the second V-shaped groove having a length extending partially across the third surface, and with an edge of the first conductive terminal at the third surface being curved to have the rounded shape. The semiconductor package further includes a second conductive terminal having third and fourth ends and a fourth surface facing the same direction as the second surface. The fourth surface includes a third V-shaped groove, with the third V-shaped groove having a length extending partially across the fourth surface. The first, second, and third V-shaped grooves may be in alignment with each other such that a line extends through the lengths of the first, second, and third V-shaped grooves. An edge of the second conductive terminal at the fourth surface is curved to have the rounded shape. The semiconductor package also includes a mold compound covering the semiconductor die, the die pad, and the first and second conductive terminals. The mold compound fills the first, second, and third V-shaped grooves, and the first and third ends extend to an exterior of the mold compound. The grooves mechanically act to prevent mold compound delamination, thereby mitigating the risk of the various technical challenges described above.

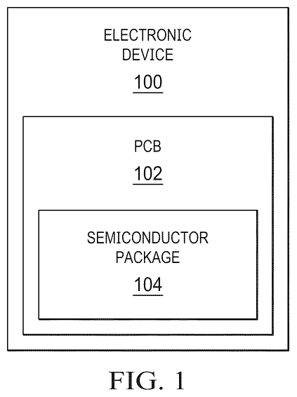

FIG. 1 is a block diagram of an electronic device including a semiconductor package having grooves to inhibit mold compound delamination, in accordance with various examples. In particular, FIG. 1 depicts an electronic device 100, which may be any suitable device, such as an automobile, an aircraft, a watercraft, a spacecraft, a video game console, a smartphone, an entertainment device, an appliance, a laptop computer, a desktop computer, a tablet, a notebook, or any other suitable type of device or system. The electronic device 100 may include a printed circuit board (PCB) 102. Various components may be coupled to the PCB 102, such as a semiconductor package 104. Other components, such as circuitry that is configured to interact with the semiconductor package 104, may also be coupled to the PCB 102. The semiconductor package 104 includes components having mold compound delamination-inhibiting grooves, as described in greater detail below.

The semiconductor package 104 may be of any suitable type, such as a small outline transistor (SOT) package, small outline package (SOP), dual inline package (DIP), quad flat no lead package (QFN), quad flat package (QFP), ball grid array (BGA) package, and so on. Other types of packages not specifically enumerated herein are contemplated and included in the scope of this disclosure.

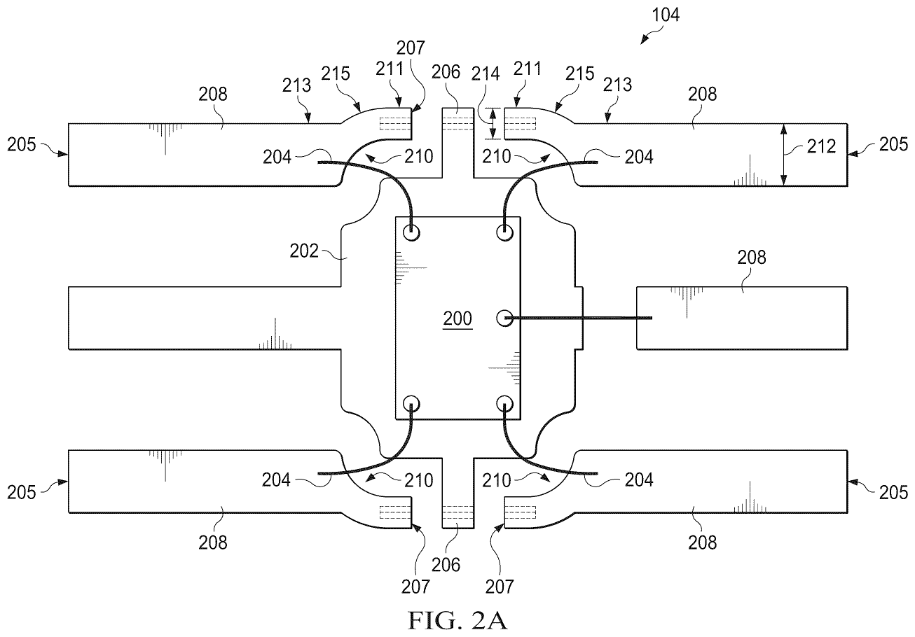

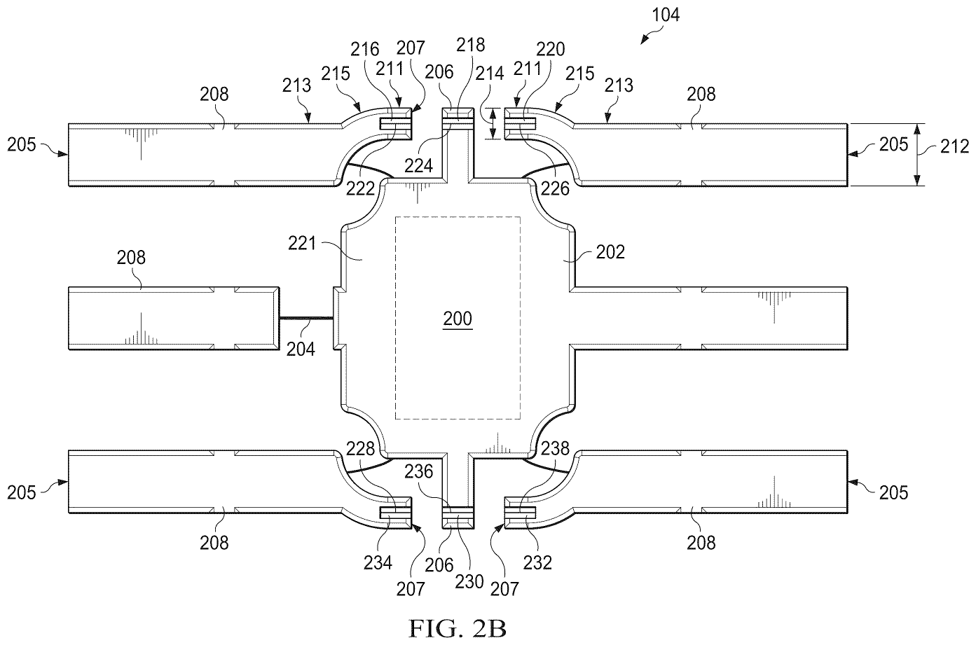

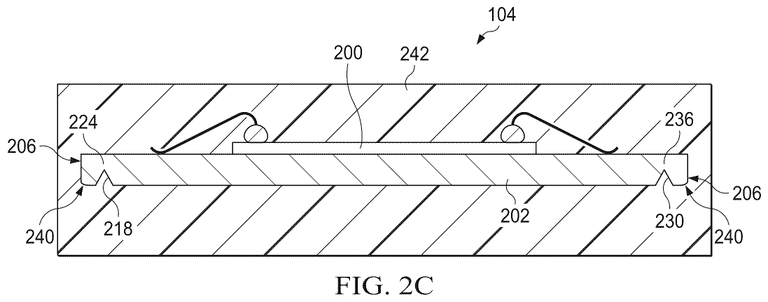

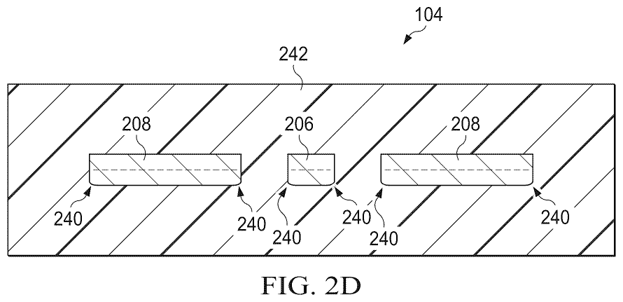

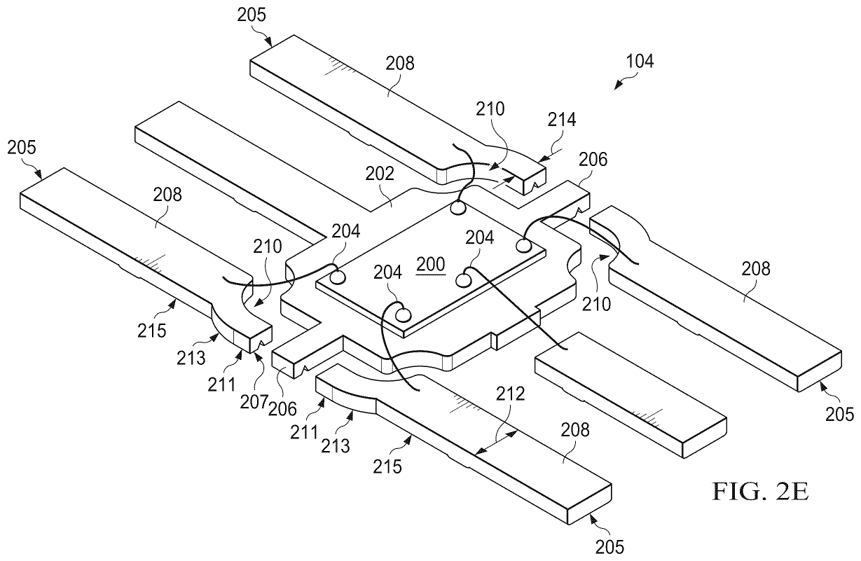

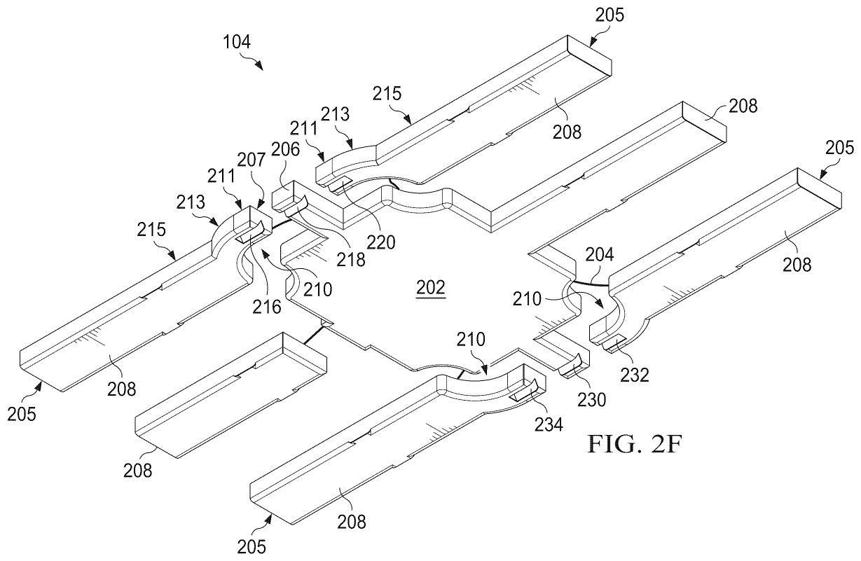

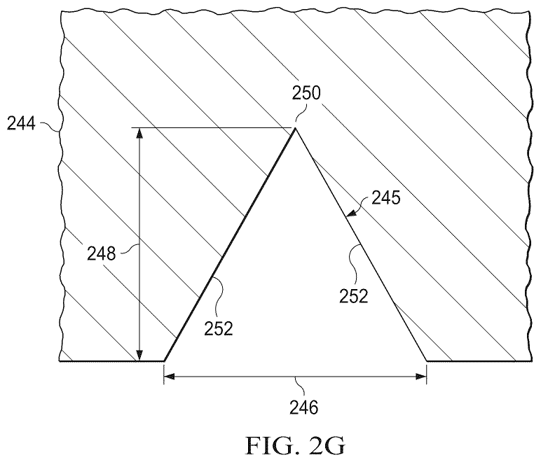

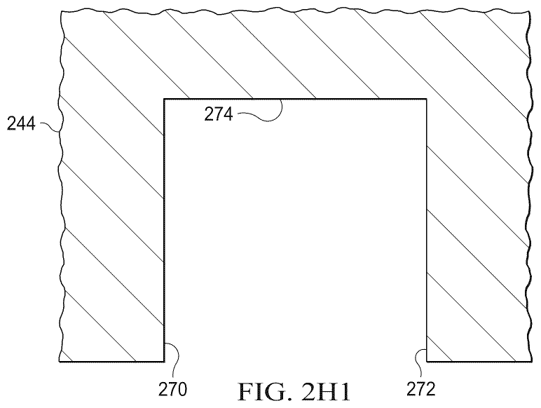

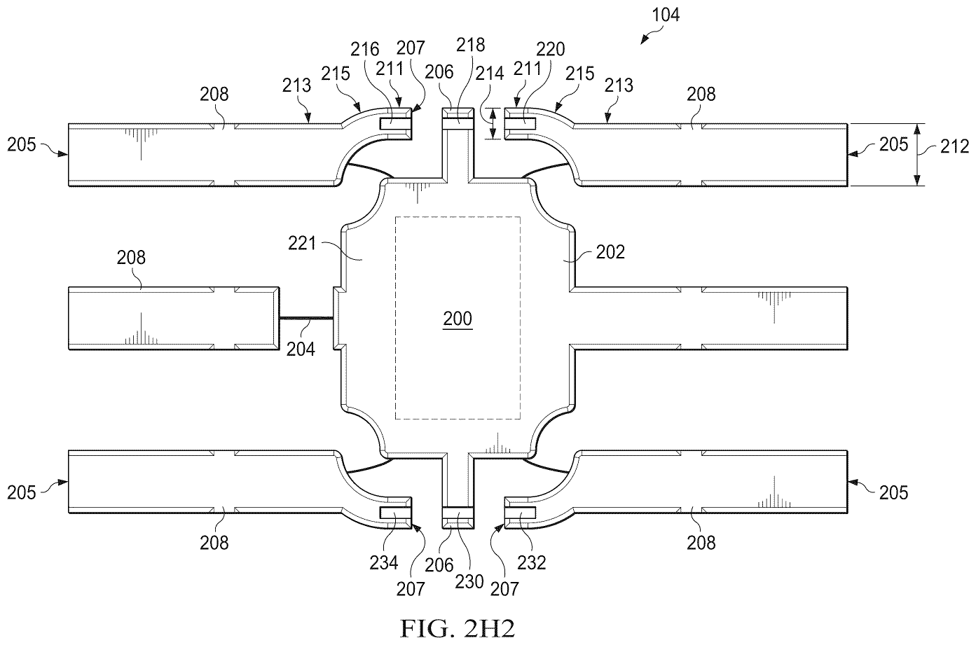

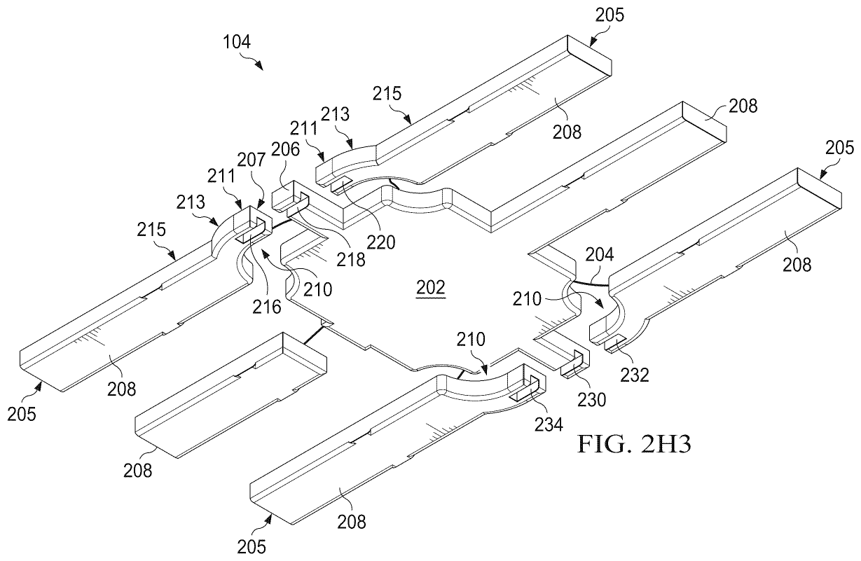

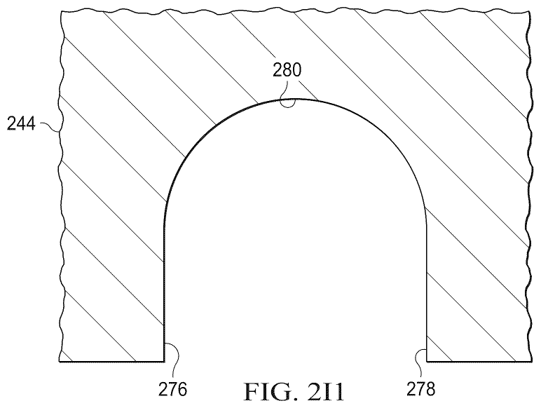

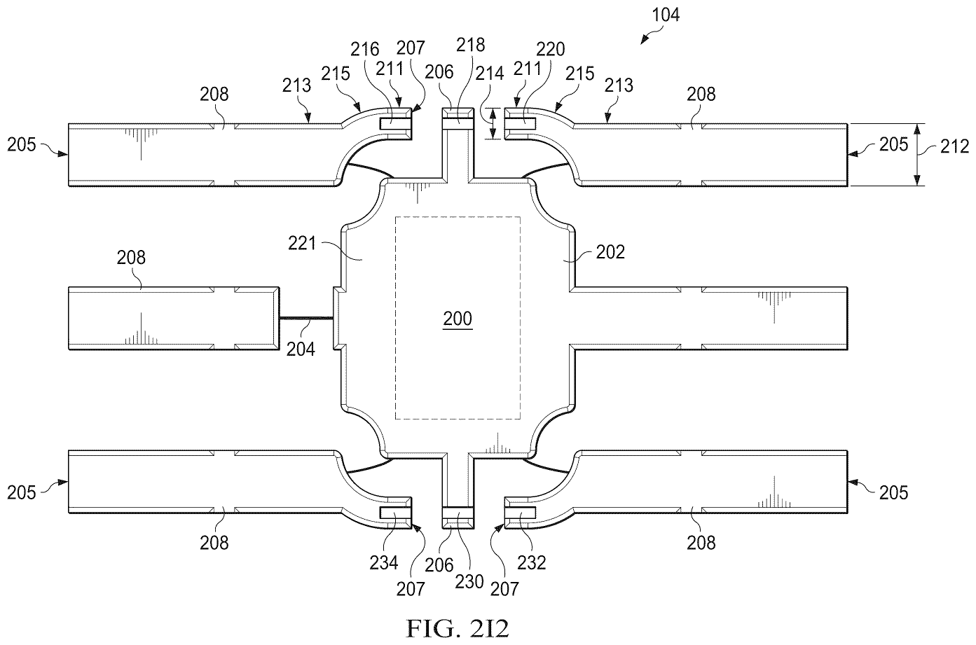

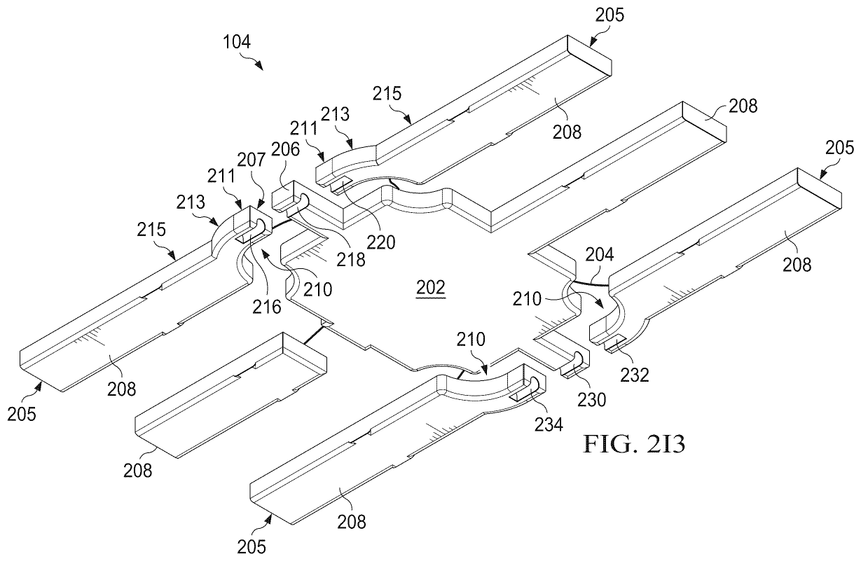

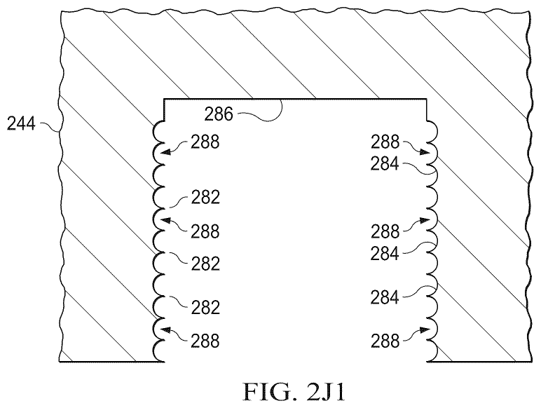

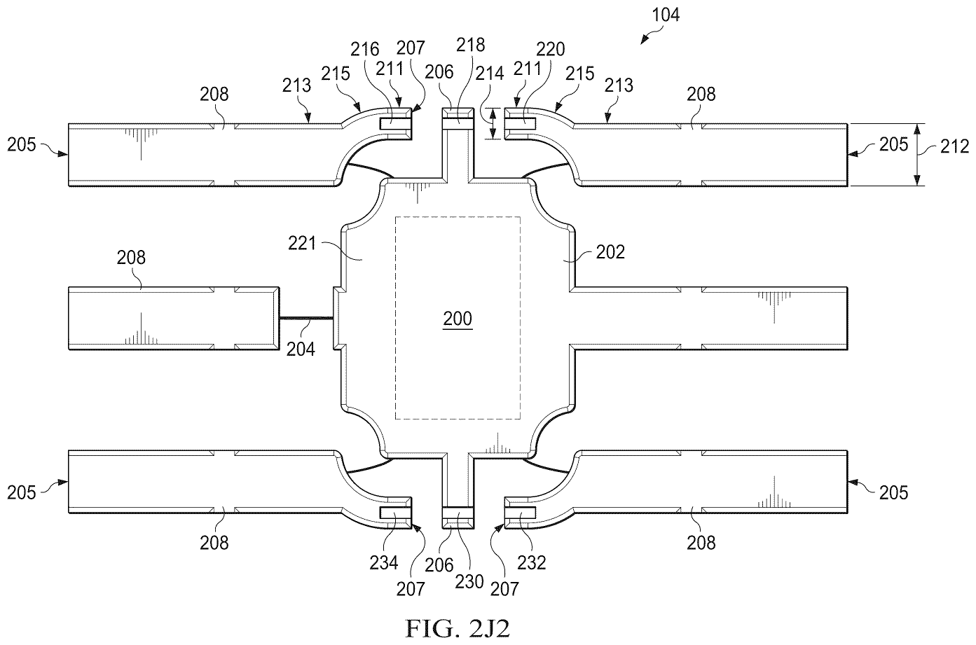

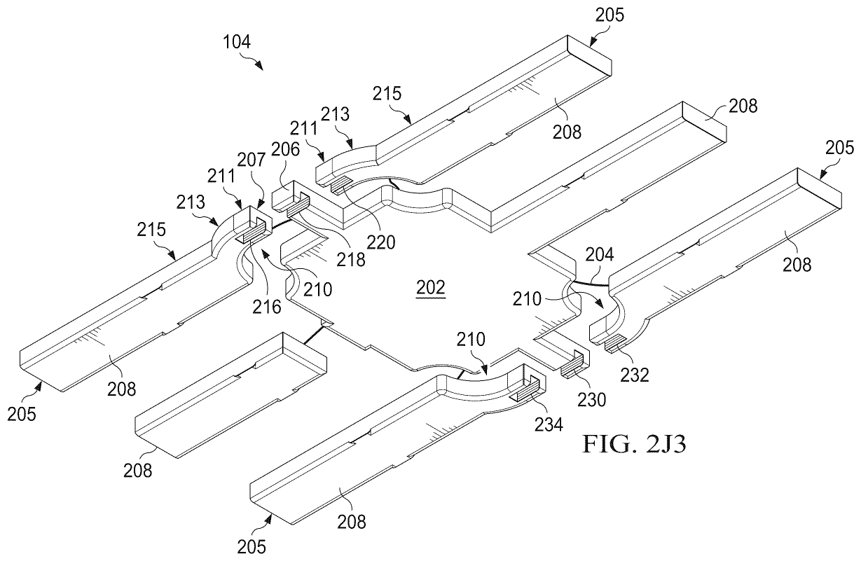

FIG. 2A is a top-down view of a die pad and conductive terminals having grooves to inhibit mold compound delamination, in accordance with various examples. In particular, FIG. 2A shows example contents of the semiconductor package 104 (FIG. 1), including a semiconductor die 200 coupled to a die pad 202 using, for example, a die attach material that is not visible in this view. The die pad 202 includes an extension 206 that extends away from the center of the die pad 202, where the semiconductor die 200 is located. The die pad 202 may be adapted to be coupled to a ground terminal, for example.

The die pad 202, including the extension 206, may be composed of any suitable metal or alloy, such as copper. The die pad 202, including the extension 206, may have a symmetric or asymmetric shape. The shape of the die pad 202, including that of the extension 206, may be polygonal or non-polygonal.

The semiconductor package 104 may further include conductive terminals 208. The conductive terminals 208 are separated from adjacent extensions 206 by gaps in which no metal is positioned. Thus, for example, the top extension 206 in FIG. 2A is separated from the conductive terminal 208 on the top left and the conductive terminal 208 on the top right by metal-free gaps, and similarly, the bottom extension 206 in FIG. 2A is separated from the conductive terminal 208 on the bottom left and the conductive terminal 208 on the bottom right by metal-free gaps.

The conductive terminals 208 may have symmetric or asymmetric shapes, and polygonal or non-polygonal shapes. The shape of each conductive terminal 208 may differ from that of another conductive terminal 208. In examples, each conductive terminal 208 has an end 205, an end 207 opposite the end 205, and an edge 211. The distal end of each extension 206 may be aligned with each adjacent edge 211 such that a single line may extend through a pair of edges 211 and the distal end of the extension 206 between those two edges 211. In the example of FIG. 2A, a line may extend through the top pair of edges 211 and the distal end of the extension 206 between those two edges 211. Similarly, in FIG. 2A, a line may extend through the bottom pair of edges 211 and the distal end of the extension 206 between those two edges 211.

One or more of the conductive terminals 208 may include a concavity 210. The concavity 210 faces the die pad 202, as shown. The concavity 210 is caused by a curved portion 215 of the conductive terminal 208 that is located between the opposing ends 205 and 207. The curved portion 215 causes the edge 211 to be displaced distally relative to an edge 213 such that the edges 211, 213 are not aligned (i.e., a single line does not extend through both edges 211 and 213).

Each of the conductive terminals 208 has a width 212 closer to the end 205 and a width 214 closer to the end 207. The width 212 is greater than the width 214, meaning that the width of the conductive terminal 208 tapers from the end 205 going toward the end 207.

Bond wires 204 couple the semiconductor die 200 (e.g., a device side of the semiconductor die 200 having circuitry formed therein) to the conductive terminals 208, as shown. The surfaces of the die pad 202 and the conductive terminals 208 shown in FIG. 2A, which may be referred to herein as the “front surfaces” of the die pad 202 and the conductive terminals 208, may be plated with a suitable metal or alloy, such as silver. Plating the front surfaces with silver may be useful because silver mitigates copper oxidation and facilitates wire bonding.

FIG. 2B is a bottom-up view of the structure of FIG. 2A, in accordance with various examples. Back surfaces 221 may include one or more grooves formed therein. FIG. 2B shows example grooves 216, 218, 220, 228, 230, and 232. The grooves 216, 218, 220, 228, 230, and 232 are V-shaped, meaning that their widest apertures are at the back surfaces 221, and they progressively narrow until reaching an inner terminus. Specifically, grooves 216, 218, 220, 228, 230, and 232 terminate at inner terminuses 222, 224, 226, 234, 236, and 238, respectively. The grooves 218, 230 are located on the extensions 206, as shown. Each of the grooves 218, 230 may extend completely across the width of the respective extension 206 on which the groove is located. Conversely, each of the grooves 216, 220, 228, and 232 may extend incompletely across the width of the respective conductive terminal 208 on which the groove is located. The grooves 216, 218, and 220 may be aligned with each other lengthwise such that a line extends laterally through the lengths of the grooves 216, 218, and 220. Similarly, the grooves 228, 230, and 232 may be aligned with each other lengthwise such that a line extends laterally through the lengths of the grooves 228, 230, and 232.

FIG. 2C is a profile, cross-sectional view of a semiconductor package having die pad and conductive terminal grooves to inhibit mold compound delamination, in accordance with various examples. More specifically, FIG. 2C shows a profile, cross-sectional view of the semiconductor package 104, including a mold compound 242 covering the semiconductor die 200 and the die pad 202, including the extensions 206, to which the semiconductor die 200 is coupled. In FIG. 2C, the grooves 218 and 230 are visible. Further, edges 240 of the die pad 202 are rounded as shown as a result of the manufacturing process used to create the semiconductor package 104, as described in greater detail below. FIG. 2D is another profile, cross-sectional view of the semiconductor package 104, taken along the lengths of the grooves 216, 218, and 220. As in FIG. 2C, bottom edges 240 shown in FIG. 2D are rounded due to the manufacturing process used to create the semiconductor package 104, as described in greater detail below. The mold compound 242 covers the extension 206 and the conductive terminals 208.

FIG. 2E is a top-side perspective view of the structure of FIG. 2A, in accordance with various examples. FIG. 2F is a bottom-side perspective view of the structure of FIG. 2A, in accordance with various examples.

FIG. 2G is a cross-sectional view of a component 244 having a V-shaped groove 245 formed therein. The example component 244 is representative of the various structures shown in FIGS. 2A-2F, such as the extensions 206 and the conductive terminals 208. The example groove 245 is representative of the various grooves shown in FIGS. 2B, 2C, and 2F, such as the grooves 216, 218, 220, 228, 230, and 232. The example groove 245 has an inner terminus 250 and walls 252. The walls 252 gradually slope toward each other as the walls 252 approach the inner terminus 250. A depth 248 of the groove 245 ranges between 5 microns and 25 microns, with a depth below this range being disadvantageous because it is inadequate for proper mold compound locking, and with a depth above this range being disadvantageous for lead frame deformation, as the total lead frame thickness is approximately 5 mils. The depth 248 of the groove 245 is between 4% and 20% of the thickness of the component 244 (e.g., the extensions 206, or the conductive terminals 208), with a depth below this range being disadvantageous because it is inadequate for proper mold compound locking, and with a depth above this range being disadvantageous for lead frame deformation, as the total lead frame thickness is approximately 5 mils. The example groove 245 has a maximum width 246 that does not exceed 25 microns, with a maximum width that is above this range being disadvantageous because it runs afoul of common manufacturing limits and tolerances.

The various grooves are described herein as having a V-shape. However, the scope of this disclosure is not limited to grooves having any particular shape. For example, FIG. 2H1 is a cross-sectional view of a groove (e.g., grooves 216, 218, 220, 230, 232, 234) having a rectangular shape and including walls 270 and 272 and a floor 274. The floor 274 may meet with walls 270 and 272 at approximately right angles. FIG. 2H2 is identical to FIG. 2B, except that the grooves 216, 218, 220, 230, 232, 234 have rectangular shapes instead of V shapes. FIG. 2H3 is identical to FIG. 2F, except that the grooves 216, 218, 220, 230, 232, 234 have rectangular shapes instead of V shapes.

Other shapes are contemplated. For example, FIG. 2I1 is a cross-sectional view of a groove (e.g., grooves 216, 218, 220, 230, 232, 234) having a rounded shape (e.g., a semi-ovoid or a semi-circular shape). When semi-ovoid, the groove of FIG. 2I1 may include a floor 280 that joins walls 276, 278 at rounded corners. In the event that the groove of FIG. 2I1 has a semi-circular cross-sectional shape, the interior surface of the groove may be rounded with no distinct walls or floors. FIG. 2I2 is identical to FIG. 2B, except that the grooves 216, 218, 220, 230, 232, 234 have semi-ovoid or semi-circular shapes instead of V shapes. FIG. 2I3 is identical to FIG. 2F, except that the grooves 216, 218, 220, 230, 232, 234 have semi-ovoid or semi-circular shapes instead of V shapes.

Still other shapes are contemplated. For instance, FIG. 2J1 is a cross-sectional view of a groove (e.g., grooves 216, 218, 220, 230, 232, 234) having a rectangular shape with striated surfaces formed by a plasma etch process. Specifically, the groove may include walls 282 and 284 meeting a floor 286 at approximately right angles. The walls 282, 284 may include striations 288 formed by the use of a plasma etch process used to create the groove. FIG. 2J2 is identical to FIG. 2B, except that the grooves 216, 218, 220, 230, 232, 234 have rectangular shapes and striations 288 instead of V shapes. FIG. 2J3 is identical to FIG. 2F, except that the grooves 216, 218, 220, 230, 232, 234 have rectangular shapes and striations 288 instead of V shapes.

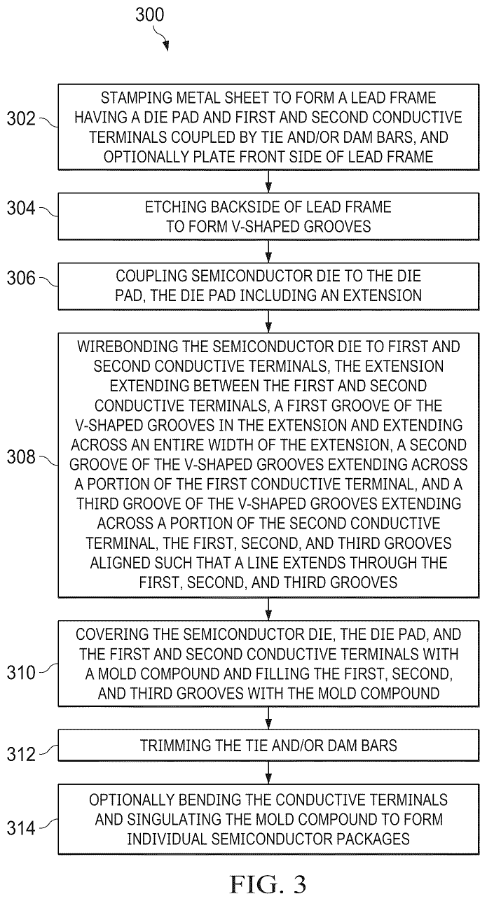

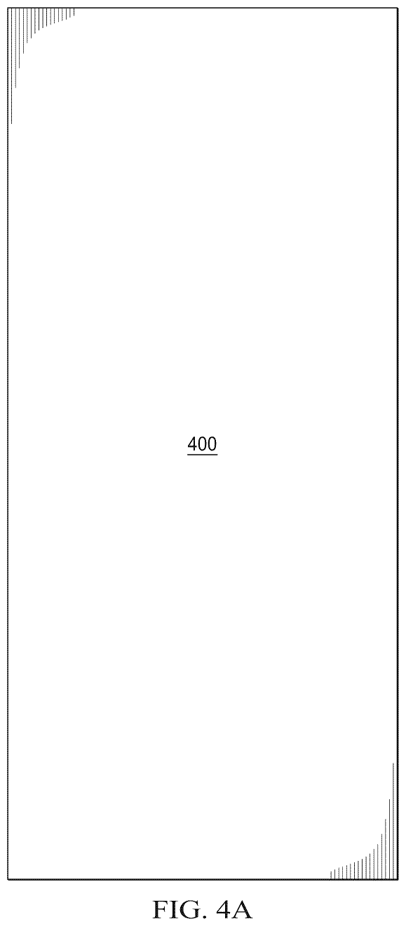

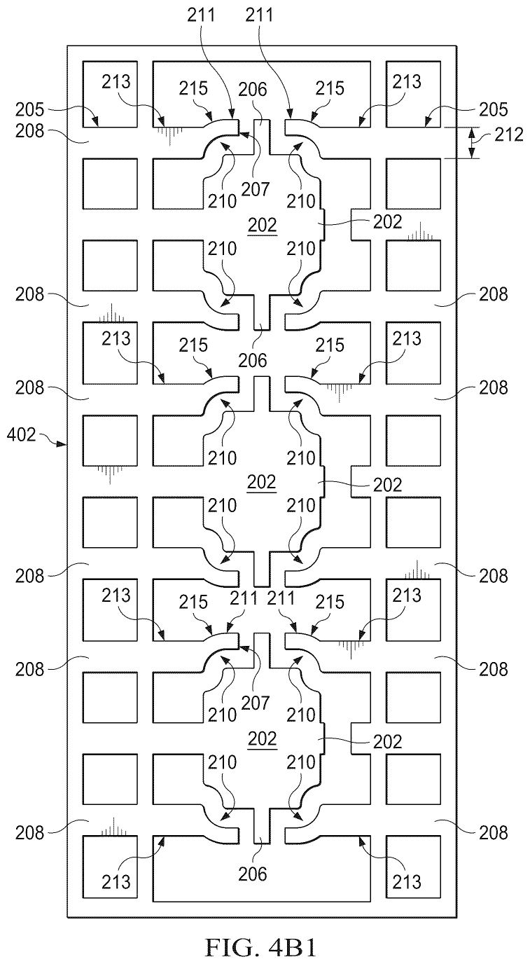

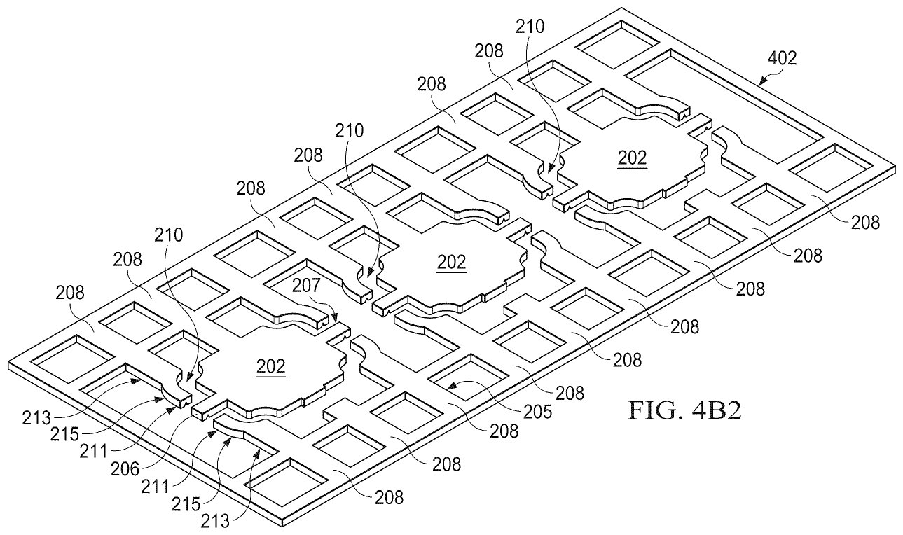

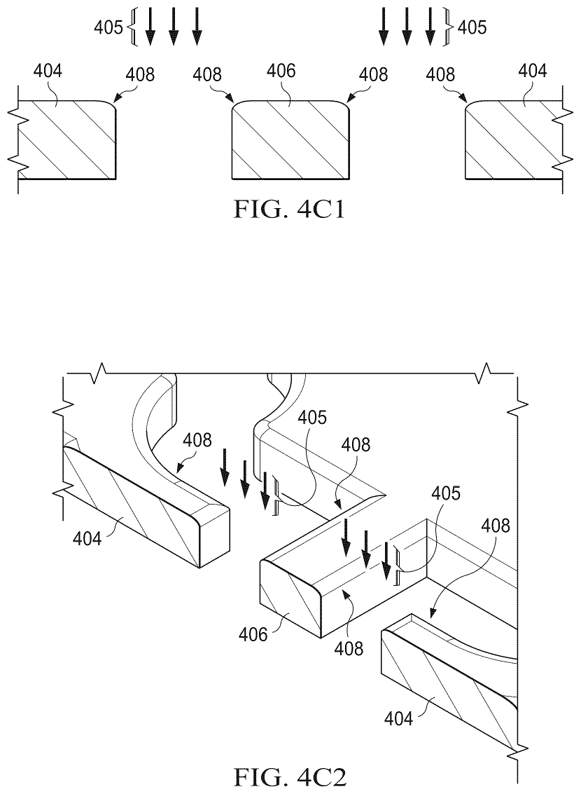

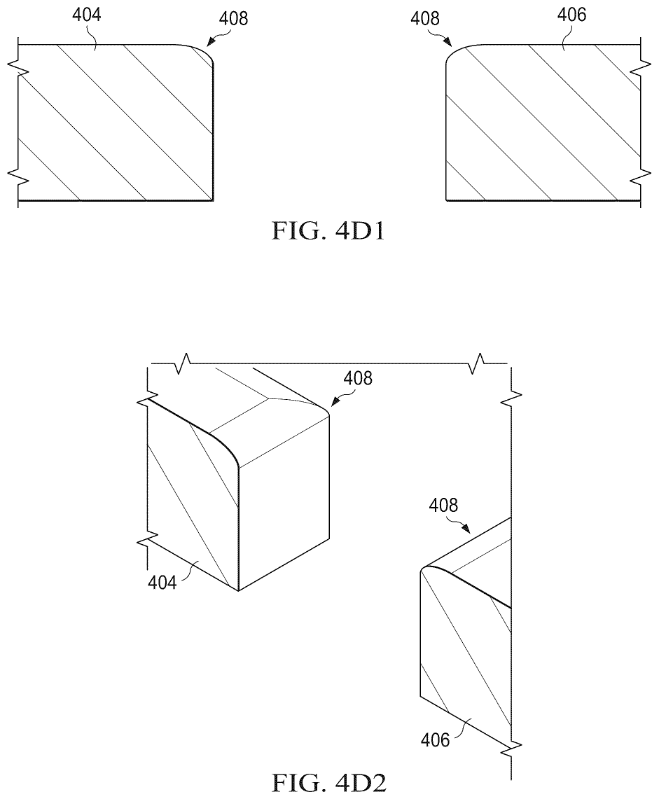

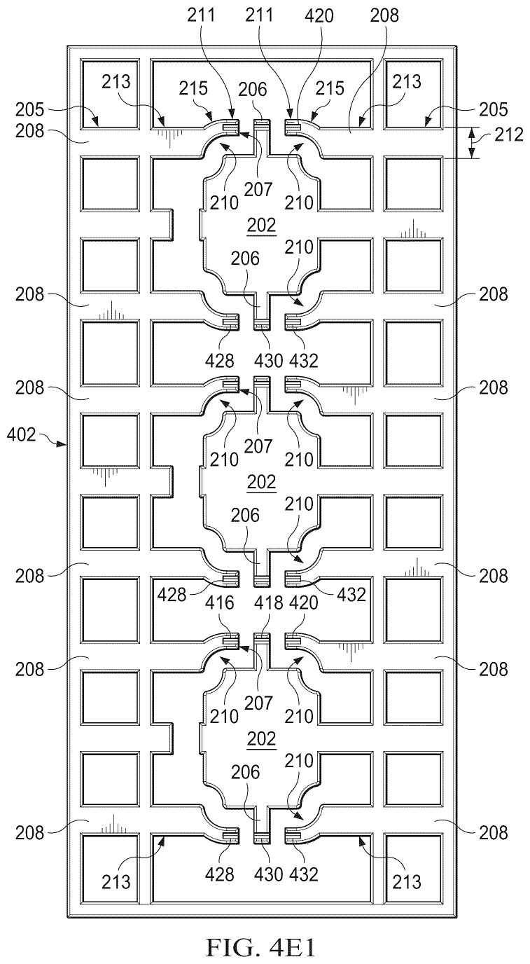

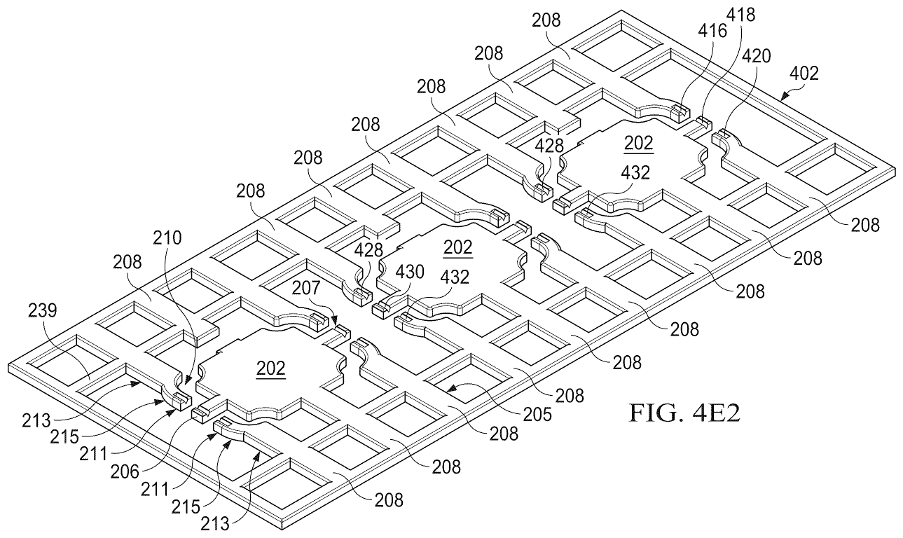

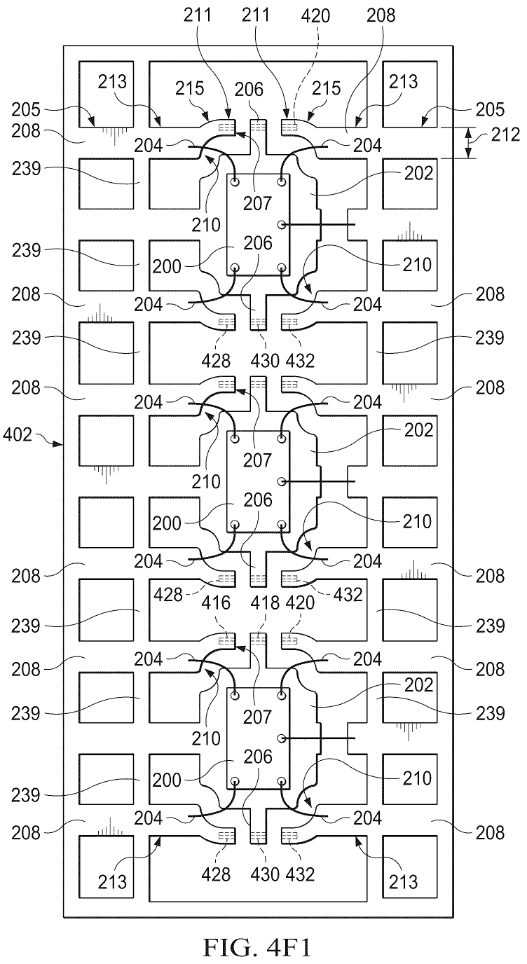

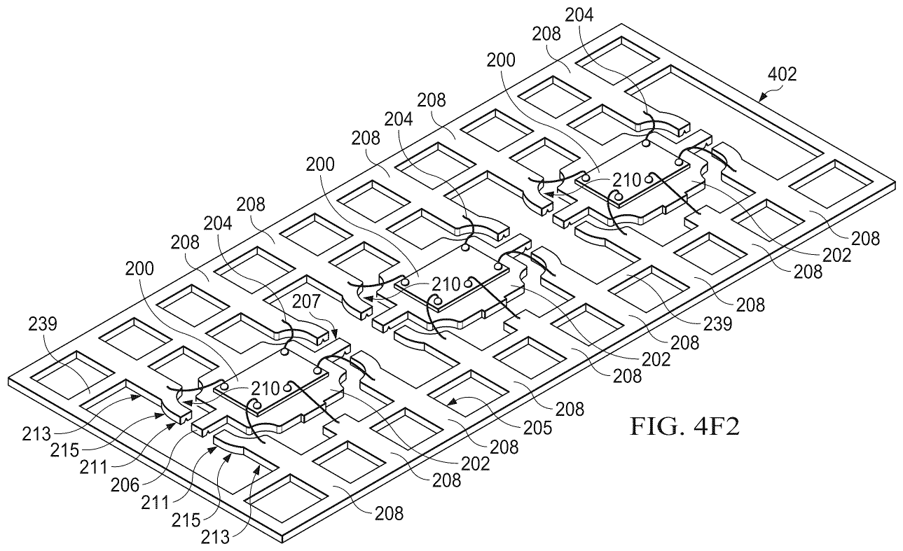

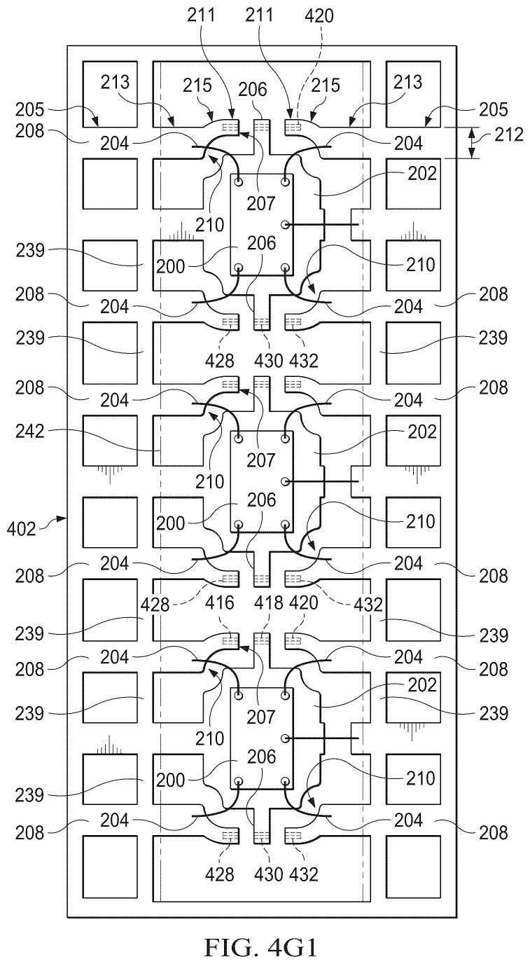

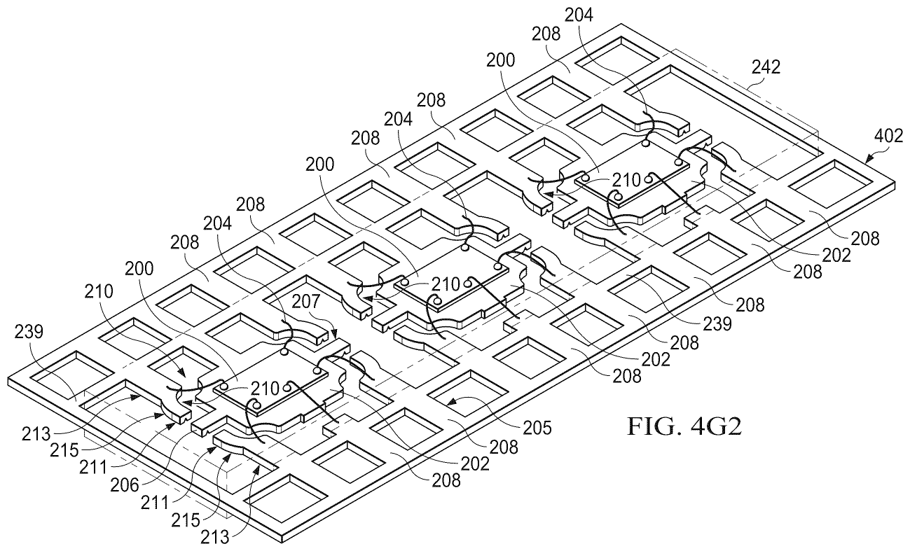

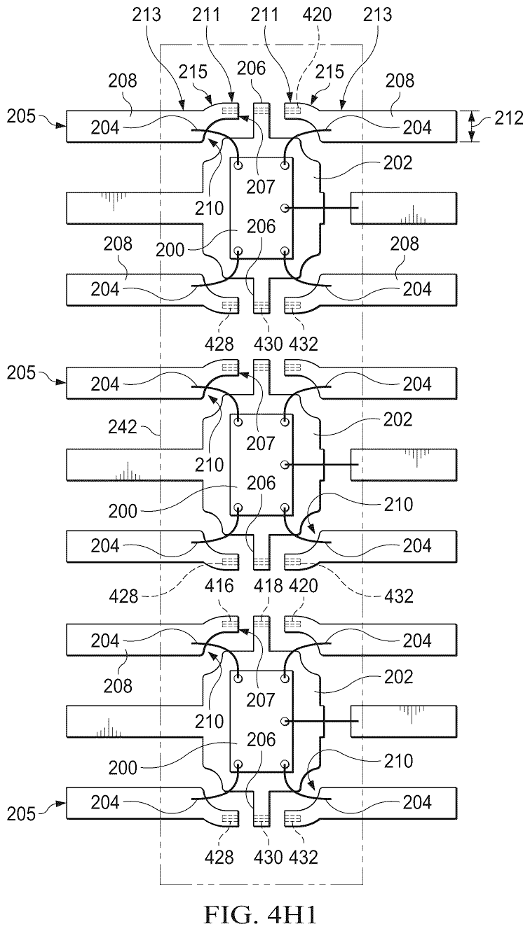

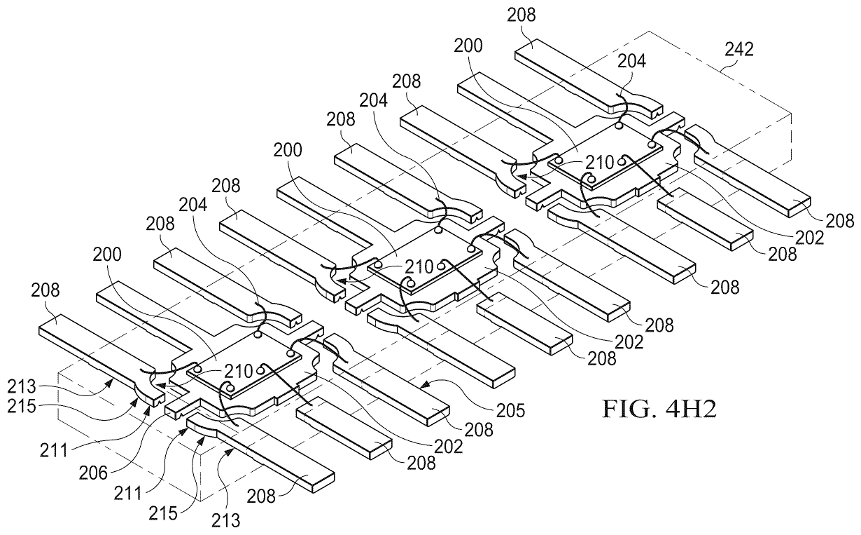

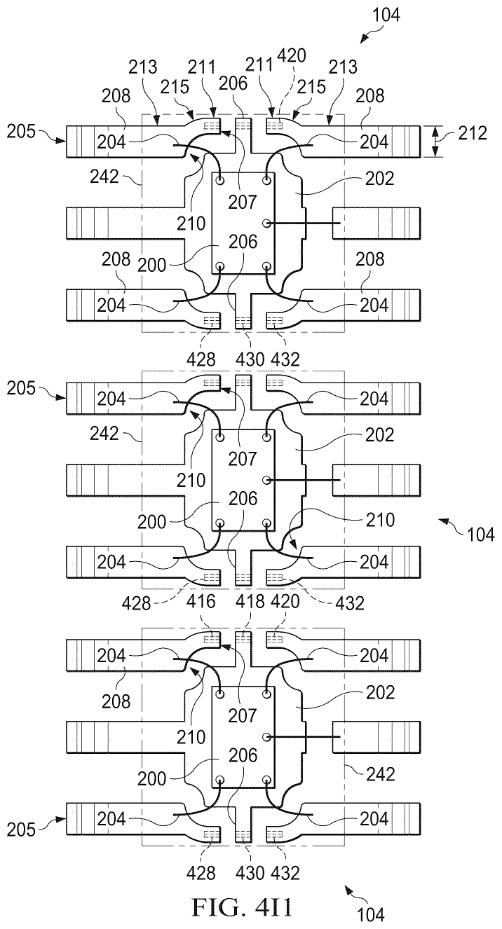

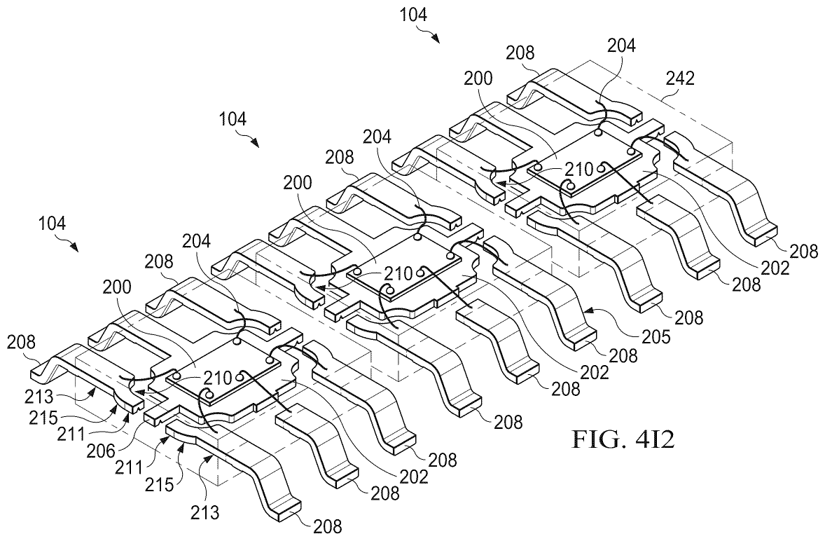

FIG. 3 is a flow diagram of a method 300 for manufacturing a semiconductor package having grooves to inhibit mold compound delamination, in accordance with various examples. FIGS. 4A-4I2 are a process flow of a method for manufacturing a semiconductor package having grooves to inhibit mold compound delamination, in accordance with various examples. Accordingly, FIGS. 3 and 4A-4I2 are now described in parallel.

The method 300 includes stamping a metal sheet to form a lead frame having a die pad and first and second conductive terminals coupled by tie and/or dam bars (302). Optionally, the front surfaces of the lead frame may be plated with a suitable metal or alloy, such as silver (302). FIG. 4A is a top-down view of a metal sheet 400, in accordance with various examples, and FIG. 4B1 is a top-down view of a lead frame strip 402 formed by stamping the metal sheet 400 (FIG. 4A). FIG. 4B2 is a perspective view of the structure of FIG. 4B1, in accordance with various examples.

As alluded to above, the manufacturing process by which the semiconductor package 104 is created causes rounding of certain edges in portions of the lead frame included in the semiconductor package 104. For example, as described above with reference to FIGS. 2C and 2D, the edges 240 of the die pad 202 and the conductive terminals 208 are rounded. This rounding of the edges 240 is caused by the stamping process performed in step 302. Such rounded edges 240 are a signature indication that a stamping process was used to create a lead frame from a sheet of metal, such as metal sheet 400. Accordingly, FIG. 4C1 depicts the stamping process being performed on the metal sheet 400, as indicated by arrows 405. The stamping process creates components 404 and 406 that are at least partially separated from each other, with components 404 being representative of the conductive terminals 208 (FIG. 2A), and with component 406 being representative of the extension 206 (FIG. 2A). The stamping process creates rounded edges 408, which are representative of the rounded edges 240 described above with reference to FIGS. 2C and 2D. The edges on the opposing side of the components 404 and 406 are not rounded and instead may be approximately right angles, as shown. FIG. 4D1 is a profile, cross-sectional view of a component, such as component 404 or 406, having a rounded edge 408. FIG. 4D2 is a perspective view of the structure of FIG. 4D1, in accordance with various examples.

The method 300 includes etching a backside of a lead frame to form V-shaped grooves (304). FIG. 4E1 is a bottom-up view of the lead frame strip 402 shown in FIG. 4B1, with V-shaped grooves 416, 418, 420, 428, 430, and 432 having been etched into the back side of the lead frame strip 402. The grooves 416, 418, 420, 428, 430, and 432 are representative of the grooves 216, 218, 220, 228, 230, and 232 described above. FIG. 4E2 is a perspective view of the structure of FIG. 4E1, in accordance with various examples.

The method 300 includes coupling a semiconductor die to the die pad, where the die pad includes an extension (306). The method 300 also includes wire bonding the semiconductor die to first and second conductive terminals, with the extension extending between the first and second conductive terminals (308). A first groove of the V-shaped grooves is in the extension and may extend across an entire width of the extension (308). A second groove of the V-shaped grooves may extend across a portion of the first conductive terminal (308). A third groove of the V-shaped grooves may extend across a portion of the second conductive terminal. The first, second, and third grooves may be aligned such that a line extends through the first, second, and third grooves (308). FIG. 4F1 is a top-down view of the structure of FIG. 4B1, except that semiconductor dies 200 have been coupled to the lead frame strip 402, and bond wires 204 have been coupled to the semiconductor dies 200 and to the conductive terminals of the lead frame strip 402.

The method 300 includes covering the semiconductor die, the die pad, and the first and second conductive terminals with a mold compound and filling the first, second, and third grooves with the mold compound (310). FIG. 4G1 is a top-down view of the structure of FIG. 4F1, except that a mold compound 242 is applied to the structures of FIG. 4F1, as shown. Dam bars 239 contain the flow of the mold compound 242 to appropriate areas. FIG. 4G2 is a perspective view of the structure of FIG. 4G1, in accordance with various examples.

The method 300 includes trimming the tie and/or dam bars from the lead frame (312). FIG. 4H1 is a top-down view of the structure of FIG. 4G1, except that the dam bars 239 have been trimmed and removed. FIG. 4H2 is a perspective view of the structure of FIG. 4H1, in accordance with various examples.

The method 300 includes optionally bending the conductive terminals, such as to create gullwing-style conductive terminals, or leads (314). The method 300 also includes singulating the mold compound to produce individual semiconductor packages (314). FIG. 4I1 is a top-down view of the same structure as FIG. 4H1 in accordance with various examples, except that the structure has been singulated into individual semiconductor packages 104, and that the conductive terminals have been bent, such as to form gullwing-style conductive terminals. FIG. 4I2 is a perspective view of the semiconductor packages 104 of FIG. 4I1, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Uses of the term “ground,” the phrase “ground voltage potential,” or similar in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “conductive terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a semiconductor die;
a die pad having a first surface coupled to the semiconductor die and a second surface opposite the first surface, the die pad including an extension that comprises a first groove in the second surface, wherein an edge of the extension at the second surface is curved to have a rounded shape;
a first conductive terminal having first and second ends and a third surface facing a same direction as the second surface, the third surface comprising a second groove, wherein an edge of the first conductive terminal at the third surface is curved to have the rounded shape;
a second conductive terminal having third and fourth ends and a fourth surface facing the same direction as the second surface, the fourth surface comprising a third groove, the first, second, and third grooves in alignment with each other such that a line extends through lengths of the first, second, and third grooves, wherein an edge of the second conductive terminal at the fourth surface is curved to have the rounded shape; and
a mold compound covering the semiconductor die, the die pad, and the first and second conductive terminals, the mold compound filling the first, second, and third grooves, and the first and third ends extending to an exterior of the mold compound.

2. The semiconductor package of claim 1, wherein the extension is between the second and fourth ends.

3. The semiconductor package of claim 2, wherein no metal is positioned in between the extension and the second end, and no metal is positioned in between the extension and the fourth end.

4. The semiconductor package of claim 1, wherein the extension has an end opposite the die pad, and wherein the first and second conductive terminals have first and second edges, respectively, that face away from the die pad, wherein the end and the first and second edges are aligned such that a second line extends along the end and the first and second edges.

5. The semiconductor package of claim 1, wherein the first, second, and third grooves have a V-shape.

6. The semiconductor package of claim 1, wherein the length of the first groove extends across an entire width of the extension.

7. The semiconductor package of claim 1, wherein the first conductive terminal includes a curved section between the first and second ends.

8. The semiconductor package of claim 1, wherein the second conductive terminal includes a curved section between the third and fourth ends.

9. The semiconductor package of claim 1, wherein a first gap is between the extension and the first conductive terminal and a second gap is between the extension and the second conductive terminal.

10. The semiconductor package of claim 1, wherein the length of the second groove extends partially across the third surface, and wherein the length of the third groove extends partially across the fourth surface.

11. The semiconductor package of claim 1, wherein the first conductive terminal has a fifth surface opposite the third surface, the fifth surface plated with silver.

12. The semiconductor package of claim 1, wherein the second conductive terminal has a sixth surface opposite the fourth surface, the sixth surface plated with silver.

13. A semiconductor package, comprising:
a semiconductor die;
a die pad having a first surface coupled to the semiconductor die and a second surface opposite the first surface, the die pad including an extension that comprises a first groove in the second surface, wherein an edge of the extension at the second surface is curved to have a rounded shape;
a first conductive terminal having first and second ends and a third surface facing a same direction as the second surface, the third surface comprising a second groove, wherein an edge of the first conductive terminal at the third surface is curved to have the rounded shape;
a second conductive terminal having third and fourth ends and a fourth surface facing the same direction as the second surface, the fourth surface comprising a third groove, the extension in between the second and fourth ends, wherein an edge of the second conductive terminal at the fourth surface is curved to have the rounded shape; and
a mold compound covering the semiconductor die, the die pad, and the first and second conductive terminals, the mold compound filling the first, second, and third grooves, and the first and third ends extending to an exterior of the mold compound.

14. The semiconductor package of claim 13, wherein the first, second, and third grooves are in alignment with each other such that a line extends through the lengths of the first, second, and third grooves.

15. The semiconductor package of claim 13, wherein the first groove has a length extending across an entire width of the extension.

16. The semiconductor package of claim 13, wherein the second groove has a length extending partially across the third surface.

17. The semiconductor package of claim 13, wherein the third groove has a length extending partially across the fourth surface.

18. The semiconductor package of claim 13, wherein the extension has an end opposite the die pad, and wherein the first and second conductive terminals have first and second edges, respectively, that face away from the die pad, wherein the end and the first and second edges are aligned such that a line extends along the end and the first and second edges.

19. The semiconductor package of claim 13, wherein the semiconductor package is a small outline transistor (SOT) package.

20. The semiconductor package of claim 13, wherein the first conductive terminal has a fifth surface opposite the third surface, the fifth surface plated with silver.

21. The semiconductor package of claim 13, wherein the second conductive terminal has a sixth surface opposite the fourth surface, the sixth surface plated with silver.

22. A semiconductor package, comprising:
a semiconductor die;
a die pad having a first surface coupled to the semiconductor die and a second surface opposite the first surface, the die pad including an extension that comprises a first V-shaped groove in the second surface;
a first conductive terminal having first and second ends and a third surface facing a same direction as the second surface, the third surface comprising a second V-shaped groove;
a second conductive terminal having third and fourth ends and a fourth surface facing the same direction as the second surface, the fourth surface comprising a third V-shaped groove, the extension in between the second and fourth ends; and
a mold compound covering the semiconductor die, the die pad, and the first and second conductive terminals, the mold compound filling the first, second, and third V-shaped grooves, and the first and third ends extending to an exterior of the mold compound.

23. The semiconductor package of claim 22, wherein the first V-shaped groove has a maximum depth that is between 4% and 20% of a thickness of the extension.

24. The semiconductor package of claim 22, wherein the first and second conductive terminals have curved sections between the first and second ends and between the third and fourth ends, respectively.

25. The semiconductor package of claim 22, wherein the first V-shaped groove extends across an entire width of the extension.

26. The semiconductor package of claim 25, wherein the first, second, and third V-shaped grooves are in alignment with each other such that a line extends through lengths of the first, second, and third V-shaped grooves.

27. A method for manufacturing a semiconductor package, comprising:
coupling a semiconductor die to a die pad, the die pad including an extension;
wire bonding the semiconductor die to first and second conductive terminals, the extension extending between the first and second conductive terminals, a first groove in the extension extending across an entire width of the extension, a second groove extending across a portion of the first conductive terminal, and a third groove extending across a portion of the second conductive terminal, the first, second, and third grooves aligned such that a line extends through the first, second, and third grooves; and
covering the semiconductor die, the die pad, and the first and second conductive terminals with a mold compound and filling the first, second, and third grooves with the mold compound.

28. The method of claim 27, wherein the first groove has a depth that is between 4% and 20% of a thickness of the extension.
